(19) United States
(12) Patent Application Publication
(10) Pub. No.: US 2017/0163268 A1
(43) Pub. Date: Jun. 8, 2017

(54) DELAY CIRCUIT, DLL CIRCUIT, AND FAULT RECOVERY METHOD OF DELAY CIRCUIT

(71) Applicant: FUJITSU LIMITED, Kawasaki-shi (JP)

(72) Inventors: Masazumi MAEDA, Yokohama (JP); Noriyuki Tokuhiro, Kawasaki (JP)

(73) Assignee: FUJITSU LIMITED, Kawasaki-shi (JP)

(21) Appl. No.: 15/333,804

(22) Filed: Oct. 25, 2016

(30) Foreign Application Priority Data
Dec. 2, 2015 (JP) 2015-235706

(51) Int. Cl. H03L 7/08; H03K 5/14; H03L 7/081

(52) U.S. Cl. CPC H03L 7/0807; H03L 7/0812; H03K 5/14

(57) ABSTRACT

A delay circuit includes: a delay line that delays an input signal in accordance with a delay setting signal and outputs the input signal as a delayed signal; and a delay line control circuit that generates the delay setting signal in accordance with delay setting data used to specify a delay value in stages and outputs the delay setting signal to the delay line, the delay line control circuit including a conversion circuit that replaces delay setting data to be modified in which a delay amount of a certain range is not obtained with respect to a change in a value of the delay setting data with normal delay setting data in which a delay amount of a certain change range is obtained and that is adjacent to the delay setting data to be modified, and outputs the delay setting data to the delay line.

### CROSS-REFERENCE TO RELATED APPLICATION

This application is based upon and claims the benefit of priority of the prior Japanese Patent Application No. 2015-235706, filed on Dec. 2, 2015, the entire contents of which are incorporated herein by reference.

### FIELD

The embodiments disclosed herein are related to a delay circuit, a delay locked loop (DLL) circuit, and a fault recovery method of the delay circuit.

### BACKGROUND

Recently, a large number of delay lines is used for timing adjustment and the like in a semiconductor device. For example, a double data rate (DDR) is known as a standard for connecting a central processing unit (controller) and an external memory (DIMM), and standards such as a DDR2, a DDR3, and a DDR4 have been developed in keeping with a higher speed of data transfer.

In the DDR standard, strict timing specifications have been defined for various electrical signals exchanged with a memory when reading data from a memory and writing data to a memory. In a semiconductor device that performs an operation that conforms to the DDR standard, a large number of delay lines (DLs) are used in a memory controller, and a delay locked loop (DLL) circuit including the DLs is also used in order to finely adjust a timing of an electrical signal.

In the delay line, a large number of buffer circuits (delay elements), each of which causing a minute delay, are provided so as to be connected in series, such that a desired delay amount is obtained by adjusting the number of buffer circuits connected (passed through). A delay amount of one delay element corresponds to a resolution for setting delay for a delay line, namely, a resolution for timing adjustment in the DLL circuit. To obtain a large maximum delay amount, the number of connected delay elements are increased. Thus, a high accuracy delay line with a large maximum delay amount involves a complex circuit and an increased circuit scale.

The DLL circuit compares the phase of a signal input to the delay line with the phase of a delayed signal that has passed through the delay line, and controls delay setting data of the delay line so that the phases match, namely, the phase is delayed by one cycle (360°). Specifically, when the phase of the delayed signal is desired to be delayed (the delay amount is desired to be increased), a control to increase the value of the delay setting data is performed, and when the phase of the delayed signal is desired to be advanced (the delay amount is desired to be decreased), a control to decrease the value of the delay setting data is performed. Delay setting data for the delay line is increased or decreased sequentially, and a value of delay setting data closest to a desired delay amount is set as the lock value of the DLL.

As described above, ideally, in the delay line, the delay amount monotonically increases by increasing the number of buffer circuits (delay elements) connected, and the delay amount monotonically decreases by decreasing the number of buffer circuits (delay elements) connected, the number of buffer circuits (delay elements) connected being controlled externally. However, due to a reason involving the process of manufacturing and the like, a fault such as a short circuit or open circuit (disconnection) may occur in a delay line delay setting signal wiring. At this time, there is an issue of a fault difficult to detect if bits adjacent to each other in a delay line delay setting signal are short-circuited. This is because it is difficult to detect a difference between delay setting signals next to each other, as the difference of the amount of delay to be set is still small. In addition, in a case of an open circuit fault, a difference in delay amounts before and after the faulty position is large, such that a monotonic increase or decrease in a delay amount is not expected with respect to an increase or decrease in the number of elements connected. Thus, the delay line may not be used as a DLL circuit. Therefore, if a delay line is faulty, it is discarded as defective, being one reason for a manufacturing yield to be lowered.

However, out of the faults for which the defective delay lines have been so far discarded, some of the faults may be processed so as to meet the specifications for a DLL circuit such that the delay lines may be treated as non-defective. The manufacturing yield will improve by recovering these defective products.

The following is a reference document.

### [Document 1] Japanese Laid-open Patent Publication No. 2015-98127.

### SUMMARY

According to an aspect of the invention, a delay circuit includes: a delay line that delays an input signal in accordance with a delay setting signal and outputs the input signal as a delayed signal; and a delay line control circuit that generates the delay setting signal in accordance with delay setting data used to specify a delay value in stages and outputs the delay setting signal to the delay line, the delay line control circuit including a conversion circuit that replaces delay setting data to be modified in which a delay amount of a certain range is not obtained with respect to a change in a value of the delay setting data with normal delay setting data in which a delay amount of a certain change range is obtained and that is adjacent to the delay setting data to be modified, based on a measurement value of a delay amount of the delayed signal corresponding to the delay setting data, and outputs the delay setting data to the delay line.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a block diagram illustrating a configuration example of a DLL circuit;

FIGS. 2A to 2D are diagrams illustrating a configuration example of a delay line;

FIGS. 3A to 3D are diagrams each illustrating an example of a relationship between a delay setting value and an actual delay amount. FIG. 3A illustrates a case of a normal delay circuit (delay unit), and FIGS. 3B to 3D respectively illustrates cases of defective and abnormal delay circuits (delay units);

FIGS. 4A and 4B are diagrams respectively illustrating examples of faulty positions at which the faults of FIGS. 3B and 3C are caused in the delay circuit (delay unit);

FIG. 5 is a diagram illustrating an example of a faulty position at which the fault of FIG. 3D is caused in the delay circuit (delay unit);

FIGS. 6A to 6C are diagrams each illustrating a locked delay setting value in the DLL circuit, wherein FIG. 6A illustrates a case in which a delay amount changes normally with respect to the delay setting data in the delay circuit (delay unit) and the DLL circuit operates normally; FIG. 6B illustrates a case in which the DLL circuit does not operate normally due to a fault in the delay circuit (delay unit); and FIG. 6C illustrates a case in which despite a fault in the delay circuit (delay unit), the DLL circuit is expected to operate normally;

FIG. 7A is a diagram illustrating a principle for determining a case in which a delay circuit (delay unit) according to an embodiment is judged faulty based on a measurement result, but delay elements are recoverable by replacing the delay setting data with the delay setting data for adjacent normal units by which a delay amount for a given variation range is obtained without an inversion of a delay amount, and FIG. 7B is a diagram illustrating a principle for determining a case in which a delay circuit (delay unit) according to an embodiment is judged faulty based on a measurement result, and delay elements are not recoverable as the delay amount exceeds an allowable range even when the delay setting data is replaced;

FIG. 8 is a diagram illustrating a configuration of the delay circuit (delay unit) that measures a delay amount;

FIG. 9 is a diagram illustrating a configuration of a test system that tests a delay amount of a delay unit provided in a semiconductor device;

FIGS. 10A and 10B are diagrams each illustrating a configuration of an integrator;

FIG. 11 is a time chart illustrating a waveform of a test signal, a delayed signal, and a test output from a logic circuit 13;

FIGS. 12A and 12B are diagrams illustrating recovering of a delay circuit (delay unit) according to the embodiment including a delay element determined faulty based on a measurement value;

FIG. 13 is a diagram illustrating an example of a configuration of a DLL circuit using the delay circuit (delay unit) according to the embodiment; and

FIG. 14 is a diagram illustrating replacement processing when a measurement value of a delay amount for delay setting data exhibits a characteristic illustrated in FIG. 7A.

### DESCRIPTION OF EMBODIMENTS

An explanation follows regarding a general delay line and DLL circuit with reference to drawings, before a delay circuit (delay unit) according to the embodiment is explained.

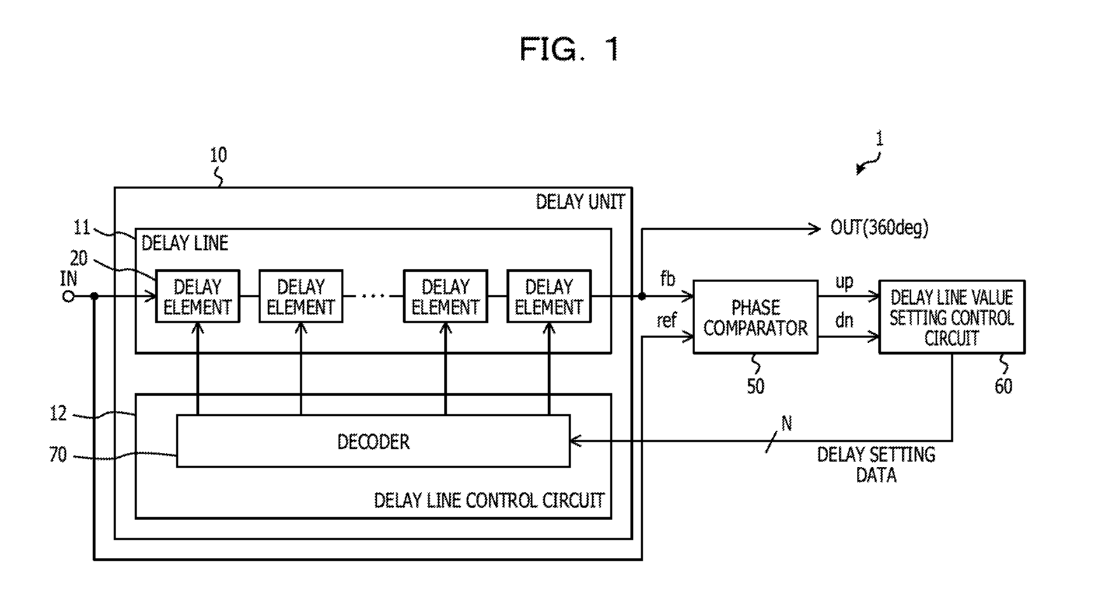

FIG. 1 is a block diagram illustrating a configuration example of a DLL circuit.

As illustrated in FIG. 1, a DLL circuit 1 includes a delay circuit (delay unit) 10, a phase comparator 50, and a delay line value setting control circuit 60. The delay circuit (delay unit) 10 includes a delay line 11 and a delay line control circuit 12. The delay line control circuit 12 includes a decoder 70 that decodes delay setting data and generates a delay line control signal supplied to each delay element 20 of the delay line 11.

As illustrated in FIG. 1, the delay line 11 delays an input signal input from a terminal IN and outputs a delayed signal fb. The phase comparator 50 sets an input signal as the reference signal ref and detects a phase difference of the delayed signal fb from the reference signal ref (input signal). The phase comparator 50 outputs “increase delay (up)” when the phase is advanced (the phase is to be delayed) and outputs “decrease delay (dn)” when the phase is delayed (the phase is to be advanced). The delay line value setting control circuit 60 generates delay setting data, increasing the delay setting data by 1 when the phase comparator 50 indicates “up”, and decreasing the delay setting data by 1 when the phase comparator 50 indicates “dn”. For example, in the delay line 11 in which the 1024 stages of delay elements 20 are connected in series, the delay setting data has 10 bits. The decoder 70 of the delay line control circuit 12 decodes the delay setting data and generates a control signal that sets the control signal CONT for one of the plural (1024 in this example) delay elements 20 forming the delay line 11 to “H” and sets the control signals CONT for all the other delay elements 20 to “L”.

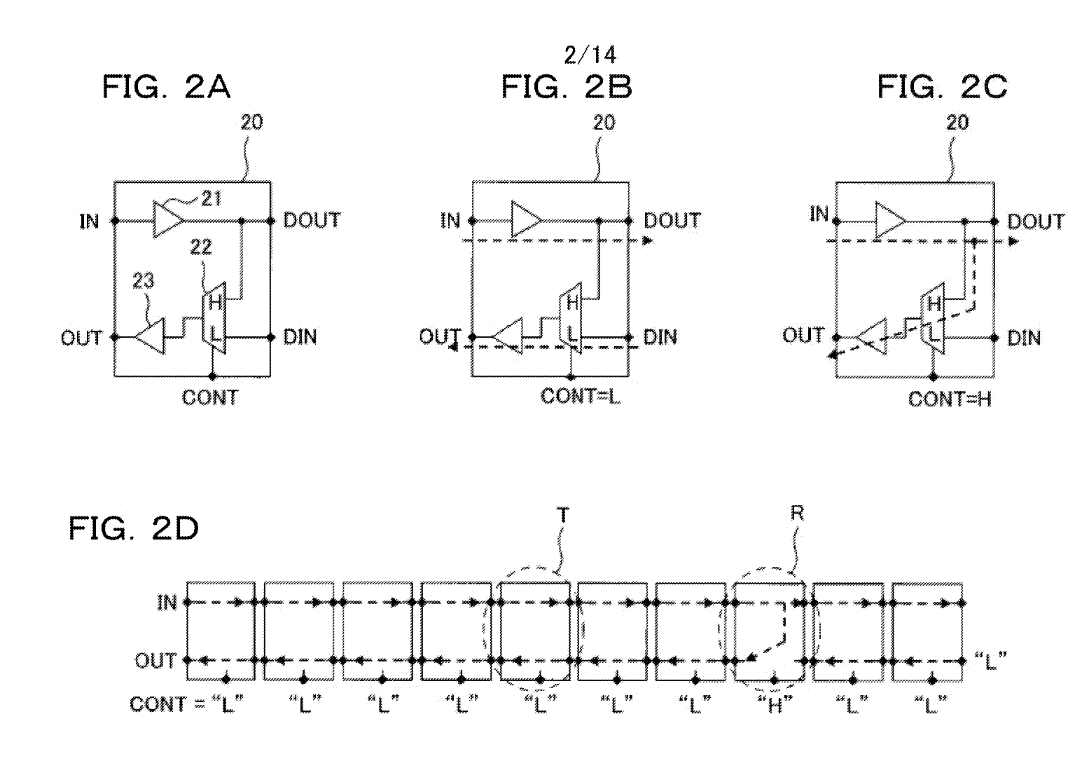

FIG. 2A to 2D are diagrams each illustrating a configuration example of the delay line. As illustrated in FIG. 2D, the delay line 11 is formed by connecting a large number of delay elements 20 in series. Here, an explanation follows regarding the delay line 11 in which 1024 delay elements 20 are connected in series as an example. The delay element 20 includes a buffer 21, a selector 22, and a buffer 23. The buffer 21 delays a signal IN from the preceding stage and outputs a signal DOUT to the following stage. The selector 22 selects one out of the signal output from the buffer 21 and a signal DIN from the following stage according to a control signal CONT. The buffer 23 delays a signal output from the selector 22 and outputs a signal OUT to the preceding stage. Generally, the buffers 21 and 23 are respectively implemented by two inverters connected in series. The selector 22 is implemented by two transfer gates. The delay element 20 may be implemented by using an inverter instead of the buffer, and using an NAND gate or the like instead of the selector.

As illustrated in FIG. 2B, when the control signal is set to “CONT=L (low)”, the selector 22 selects and outputs the signal DIN from the following stage. Thus, as indicated by the broken line, the delay element 20 in this state adopts a through operation state in which the signal IN from the preceding stage is passed through the buffer 21 and output to the following stage, and the signal DIN from the following stage is passed through the selector 22 and the buffer 23 and output to the preceding stage.

As illustrated in FIG. 2C, when the control signal is set to “CONT=H (high)”, the selector 22 selects and outputs a signal output from the buffer 21. Thus, as indicated by the broken line, the delay element 20 in this state adopts a feedback operation state in which the signal IN from the preceding stage is passed through the buffer 21, the selector 22, and the buffer 23 and output to the preceding stage.

As illustrated in FIG. 2D, in the delay line 11, out of the large number of delay elements 20 connected in series, only in one delay element 20 the control signal CONT becomes “H”, and the control signals CONT for the other delay elements are “L”. As illustrated in FIG. 2D, in the delay line 11, it is assumed that the control signal is set to “CONT=H (high)” for a delay element 20 at the eighth stage, and the control signal is set to “CONT=L (low)” for the other delay elements 20. In this case, the delay elements 20 at the first to seventh stages are in the through operation state, and the signal input to the first stage reaches the delay element 20 in the eighth stage, where the signal is fed back toward the first stage and output from the first stage as a signal OUT. In this case, the signal input to the first stage is delayed by a delay time corresponding to eight stages, specifically a delay time due to passing through 8·2 buffers and one selector. Thus, a position at which the signal is fed back is determined by specifying the stage number for the stage for which the control signal CONT is set to “H”, thereby setting a delay time.

A control signal CONT for the delay element 20 that forms the delay line 11 is generated by the delay line control circuit 12. For example, delay setting data that specifies the delay amount in the delay line 11 to which 1024 stages of delay elements are connected, is data of 10 bits. The delay line control circuit 12 decodes the delay setting data of 10 bits, and sets one of the 1024 control signal lines to “H” and sets the other control signal lines to “L”.

A general delay line has been described above. However, various configurations of delay lines other than the configuration illustrated in FIG. 2 are known, and the delay circuit (delay unit) according to the embodiment is not limited to the form of the delay line.

When a delay circuit (delay unit) including a delay line is employed, generally, value of delay setting data is increased or decreased by one, such that a desired delay amount is obtained in the delay line. Therefore, when manufacturing a semiconductor device including a delay line, a large number of delay elements that form the delay line are produced such that all delay elements exhibit the same characteristic, namely, the same delay time. Thus, by increasing or decreasing the value of delay setting data by one, a delay amount of the delay line changes accordingly in units of one unit.

However, in the manufacturing process of a semiconductor device including the delay unit, various faults such as a short circuit and open circuit (disconnection) of a wiring and a defect in elements and the like may occur, causing a reduction in yield ratio.

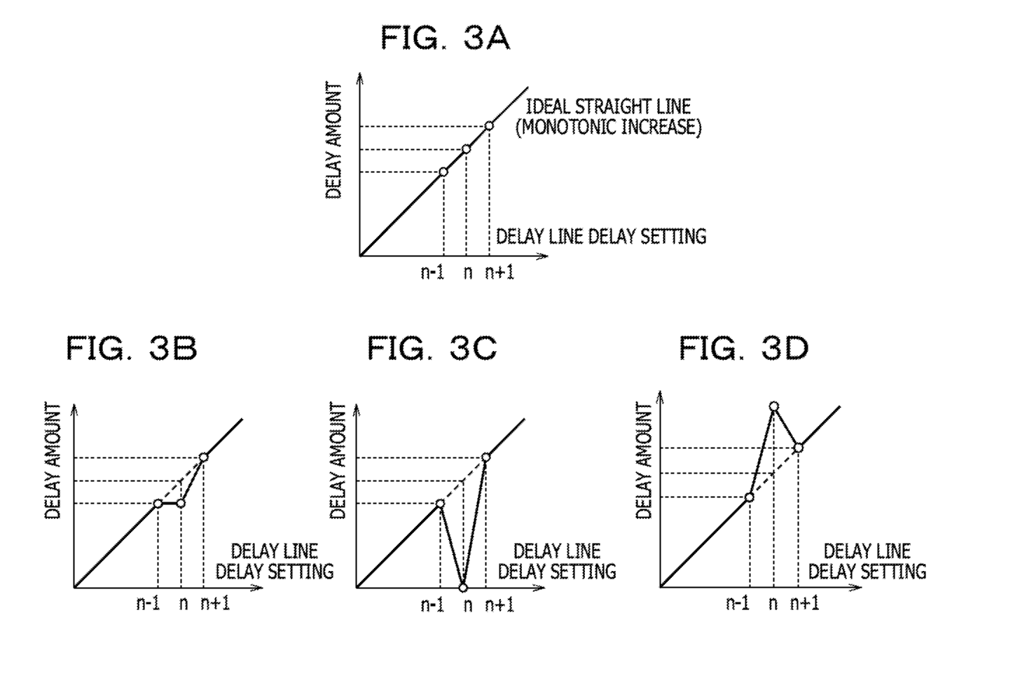

FIGS. 3A to 3D are diagrams each illustrating an example of a relationship between a delay setting value and an actual delay amount, FIG. 3A illustrating a case with a normal delay circuit (delay unit), and FIGS. 3B to 3D respectively illustrating cases of defective and abnormal delay circuits (delay units). As illustrated in FIG. 3A, in the case of the normal delay circuit (delay unit), when a value of the delay setting data (hereinafter, referred to as a delay setting value) increases one by one like n−1, n, and n+1, the delay amount also increases in proportion to the delay setting value.

In FIG. 3B, the delay amount is the same as in FIG. 3A when the delay setting value is n−1, but when the delay setting value is n, an abnormity occurs in which the delay amount does not increase, remaining the same as for the delay setting value n−1. Then, when the delay setting value is n+1, the delay amount is the same as in FIG. 3A, but has increased by two stage worth of normal amount from the amount under the delay setting value n.

In FIG. 3C, the delay amount is the same as in FIG. 3A when the delay setting value is n−1, but when the delay setting value is n, an abnormity occurs in which the delay amount greatly drops to the same level as several stages before. When the delay setting value is n+1, the delay amount is the same as in FIG. 3A, but has greatly increased from the delay amount under the delay setting value n.

In FIG. 3D, the delay amount is the same as in FIG. 3A when the delay setting value is n−1, but when the delay setting value is n, an abnormity occurs in which the delay amount becomes large and greatly increases. When the delay setting value is n+1, the delay amount is the same as in FIG. 3A, but has decreased from the delay amount under the delay setting value n.

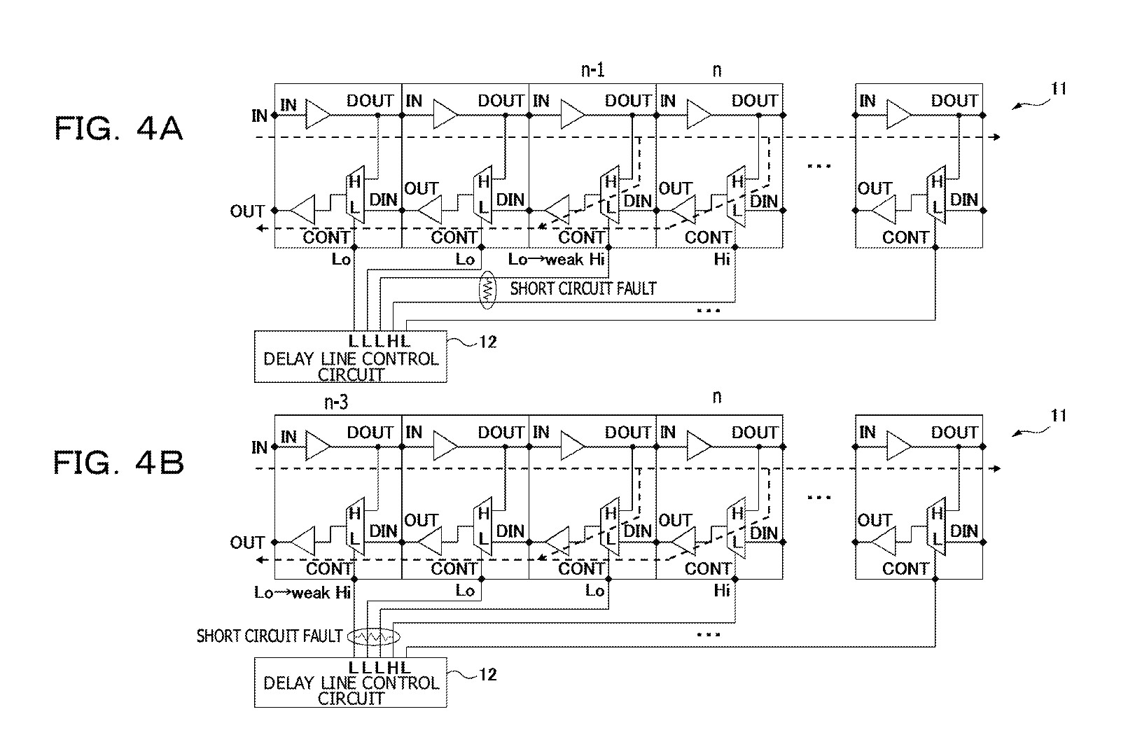

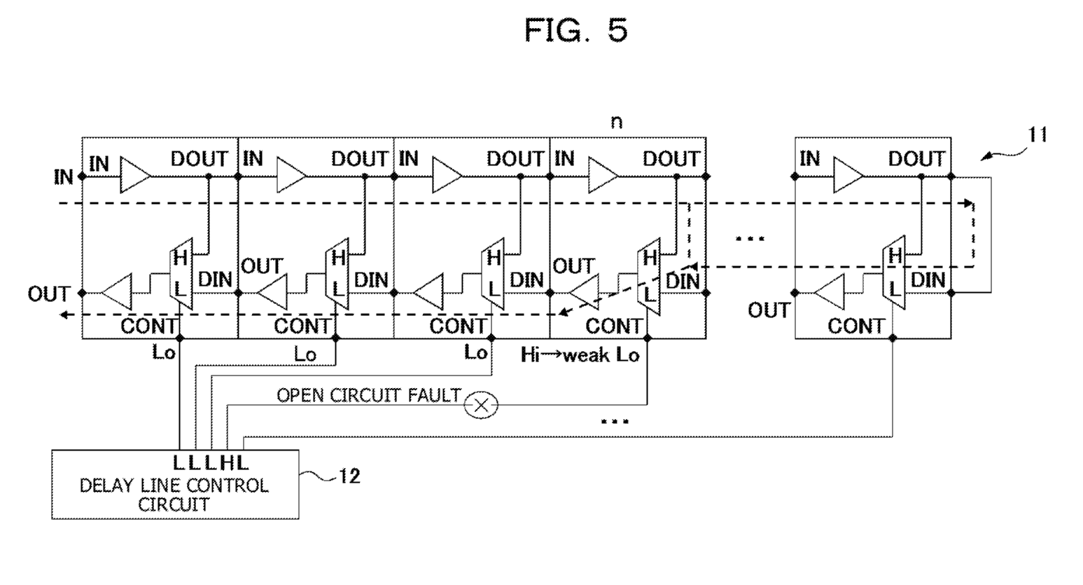

FIGS. 4A, 4B, and 5 are diagrams respectively illustrating examples of faulty positions that cause faults illustrated in FIGS. 3B to 3D in the delay unit. FIG. 4A illustrates an example of a fault that causes the fault in FIG. 3B. In this example, adjacent wirings are short-circuited between the delay line control circuit 12 of the delay unit 10 and control signal CONT terminals of the delay line 11. If the short-circuited wirings are a wiring to a control signal CONT terminal of a delay element at the n−1th stage and a wiring to a control signal CONT terminal of a delay element at the nth stage, the delay amounts become the same regardless of whether the delay line delay setting value is n−1 or n. However, when a control signal CONT terminal of a delay element at another stage is selected and set to “H”, a normal delay amount is obtained.

FIG. 4B illustrates an example of a fault that causes the fault in FIG. 3C. In this example, separated wirings are short-circuited between the delay line control circuit 12 of the delay unit 10 and the control signal CONT terminals of the delay line 11. If the short-circuited wirings are a wiring to a control signal CONT terminal of a delay element at the n−3th stage and a wiring to the control signal CONT terminal of the delay element at the nth stage, the delay amounts become the same regardless of whether the delay line delay setting value is n−3 or n. However, when a control signal CONT terminal of a delay element at another stage is selected and set to “H”, a normal delay amount is obtained.

FIG. 5 illustrates an example of a fault that causes the fault in FIG. 3D. In this example, open circuit (disconnection) occurs part way through a wiring from the delay line control circuit 12 of the delay unit 10 to the control signal CONT terminal of the delay element at the nth stage of the delay line 11. In this case, even when the delay element at the nth stage is selected as a feedback position, an input signal is not fed back at this stage, and is fed back at the last stage of the delay line, maximizing the delay amount. However, when a control signal CONT terminal of a delay element at another stage is selected and set to “H”, a normal delay amount is obtained.

Note that, in the delay element 20 that forms a delay line, when an open circuit (disconnection) occurs at a position other than a wiring to the “H” side of the selector, a delayed signal does not appear at all even when the relevant stage or a following stage is selected as a feedback position. However, the delay line functions normally up to the immediately preceding stage. In addition, when an open circuit (disconnection) occurs in the wiring to the “H” side of the selector, the change illustrated in FIG. 3D and similar to the fault of FIG. 5 will result. Furthermore, there may also be a fault such as the one in which a wiring from the delay line control circuit 12 to the control signal CONT terminal of the delay line 11 is short-circuited to GND or VCC.

In the delay circuit (delay unit) and the DLL circuit described below according to the embodiment, a delay amount of a delayed signal for each unit corresponding to the delay setting data in the delay unit is measured, whether there is a fault determined based on the measurement value, and whether the fault is recoverable is judged.

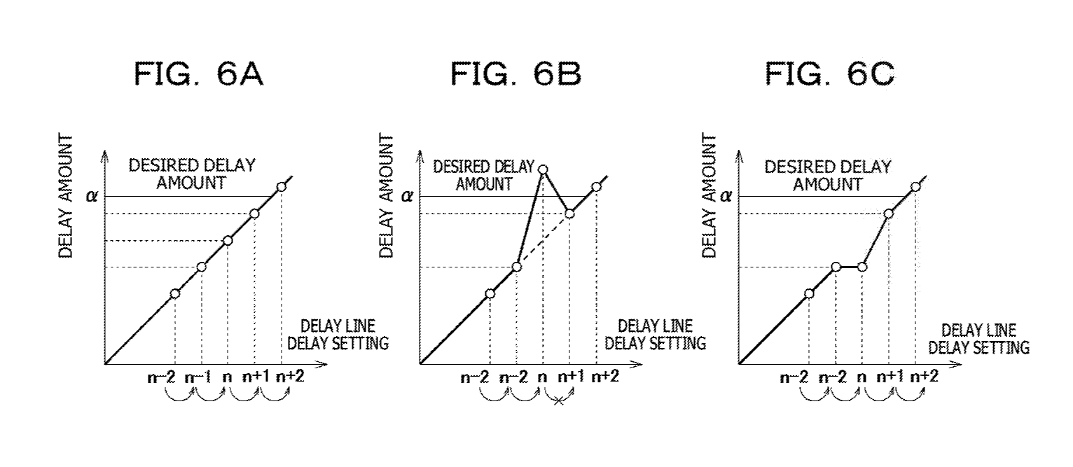

FIGS. 6A to 6C are diagrams each illustrating a locked delay setting value in the DLL circuit, wherein FIG. 6A illustrates a case in which a delay amount changes normally with respect to the delay setting data in the delay circuit (delay unit), and the DLL circuit operates normally, FIG. 6B illustrates a case in which the DLL circuit does not operate normally due to a fault in the delay circuit (delay unit), and FIG. 6C illustrates a case in which despite a fault in the delay circuit (delay unit), the DLL circuit is expected to operate normally.

When a desired delay amount in the delay line is a, assuming a delay characteristic of the delay unit 10 in which a delay amount monotonically increases as illustrated in FIG. 6A, the delay setting value is “n+2”. In contrast thereto, when the delay characteristic of the delay unit 10 is as illustrated in FIG. 6B, the locked-in delay setting value is “n”, which is incorrect. This is because, as the delay amount exceeds the desired delay amount at the point when the delay setting value is changed from “n−1” to “n”, a control to further increase the delay amount according to a change from “n” to “n+1” has not been performed.

In addition, when the delay characteristic of the delay unit 10 is as illustrated in FIG. 6C, no problem is caused because the lock is performed at “n+2”.

As described above, a delay circuit (delay unit) provided to a DLL circuit is usable if the delay characteristic of the delay circuit is such that the delay amount does not change from the preceding stage even when the delay setting value is increased. However, if a delay characteristic exhibit an inverse delay characteristic such that an increase in the delay setting value decreases the delay amount from the preceding stage, or a decrease in the delay setting value increases the delay amount from the following stage, the delay circuit is unusable in a DLL circuit.

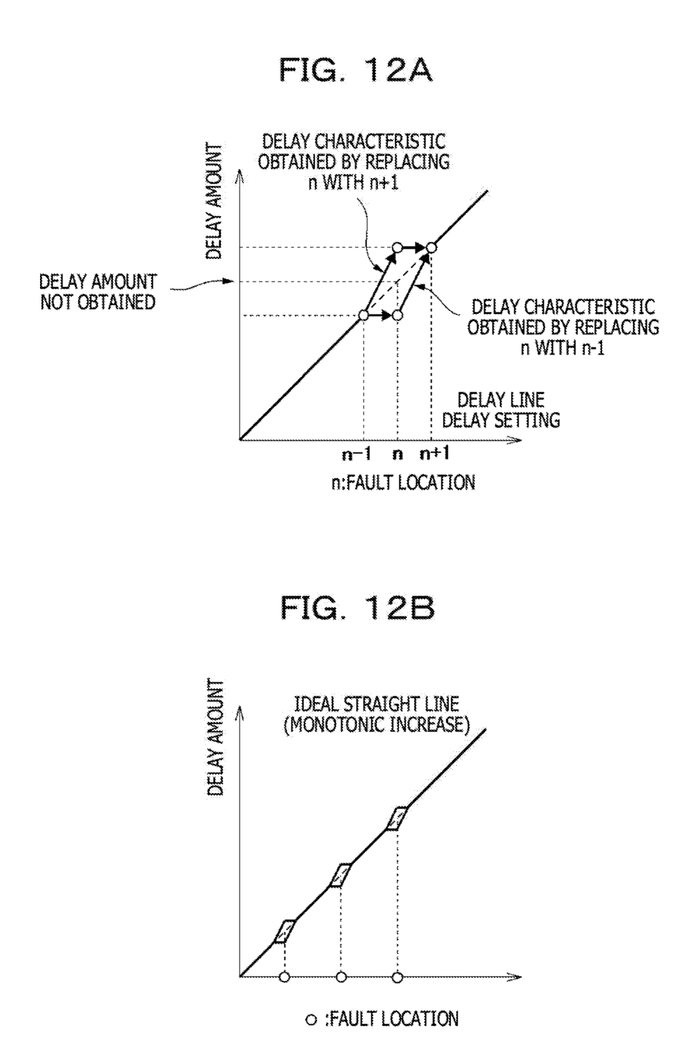

FIG. 12A is a diagram illustrating a recovering of a delay circuit (delay unit) in the embodiment including a delay element judged to be unusable based on a measurement value.

As illustrated in FIG. 12A, delay setting data n judged to indicate the faults illustrated in FIGS. 3C and 3D (delay setting data to be modified) is replaced with a normal delay setting data (n−1 or n+1) from which a delay amount in a given variation range is obtained, in the delay circuit (delay unit) according to the embodiment. This enables the reversal of the delay amount with respect to the change in delay setting data to be suppressed, without modifying delay setting data supplied to the delay line control circuit 12. The diagram thereby explains a principle in which an unusable delay element may be recovered.

In addition, even in cases in which plural faults occurred in separated locations, the delay setting data to be modified may be used to recover the faults by replacing the delay setting data. FIG. 12B illustrates the overall characteristic of a change in a delay amount with respect to a change in a delay setting value, after a recovering processing has been executed for faults at three locations.

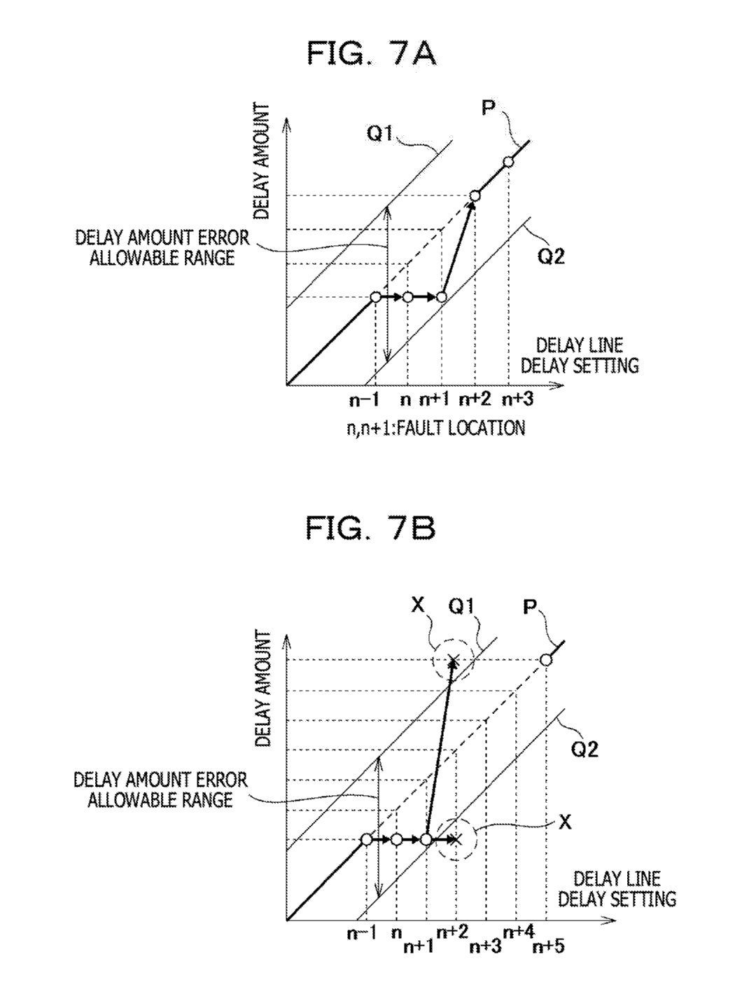

In addition, there are cases in which faults are recoverable even if two or more faults occurred continuously. As illustrated in FIG. 7A, a characteristic indicating an ideal change in delay amount assumed for a change in a delay setting value is represented by “P”. The upper limit and the lower limit of an allowable range of a delay amount error are determined with respect to the characteristic P. In FIG. 7A, “Q1” and “Q2” respectively represent the upper limit and the lower limit of the allowable range of the error. As illustrated in FIG. 7A, out of delay setting data judged to indicate a fault, the data may be used for which a change in a delay amount at each stage, measured for a change in a delay setting value after the replacement of delay setting data, is within the range between “Q1” and “Q2” and not front-back inverted. However, as illustrated in FIG. 7B, a delay circuit (delay unit) is not usable for which there are continuous faulty positions and the change in delay amount exceeds the range of Q1 and Q2 with respect to a change in the delay setting value after the replacement of the delay setting data.

In order to determine whether a delay circuit is either a non-defective product without any delay setting value for a fault, or with a delay setting value for a fault but is recoverable, a change in a delay amount of a delay line with respect to a change in a delay setting value is measured in a manufacturing process of a semiconductor device including a delay circuit (delay unit). However, a delay amount per one stage of the delay line provided in the memory controller that conforms to the DDR4 standard, for example, is approximately 2 ps to 5 ps, very small compared to a clock cycle of the circuit, making it difficult to test a delay amount of the delay line. An explanation follows regarding an example of a method in which the above-described determination is performed in the delay circuit (delay unit) according to the embodiment, and a method to measure a change in a delay amount with respect to a change in a delay setting value, information desired in recovering a delay element having a fault.

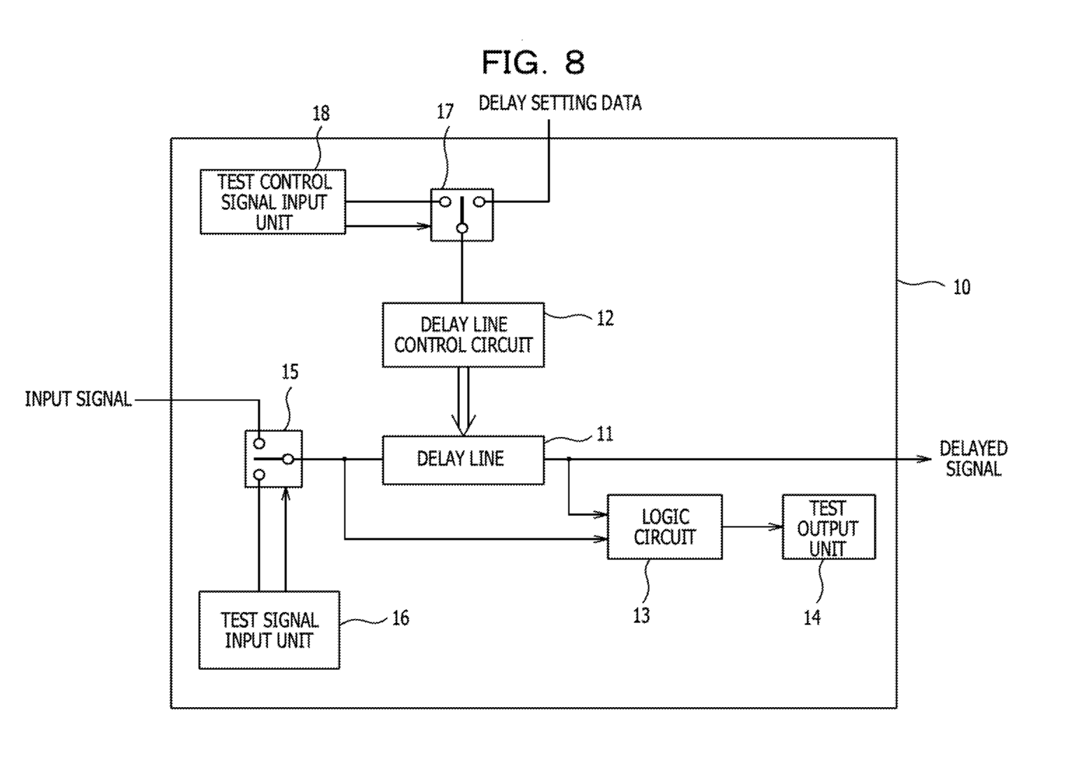

FIG. 8 is a diagram illustrating a configuration of the delay circuit (delay unit) that measures a delay amount. The delay unit 10 according to the embodiment includes a logic circuit 13 in addition to a delay line 11 and a delay line control circuit 12. The delay unit 10 according to the embodiment further includes a test output unit 14, a switch 15, a test signal input unit 16, a switch 17, and a test control signal input unit 18.

The logic circuit 13 performs logical calculation of an input signal to the delay line 11 and a delayed signal that has been delayed by the delay line 11. The logic circuit is, for example, either one of an EXOR circuit, an EXNOR circuit, an OR circuit, an NOR circuit, an AND circuit, and a NAND circuit.

The switch 15 selects an input signal at normal operation, and when the delay unit 10 is tested, the switch 15 selects a test signal input from the test signal input unit 16, and outputs the selected signal to the delay line 11 as an input signal.

The switch 17 selects delay setting data at normal operation, and when the delay unit 10 is tested, the switch 17 selects a test control signal input from the test control signal input unit 18, and outputs the selected signal to the delay line control circuit 12 as a delay setting data.

The test output unit 14 is a unit that externally outputs a logical signal that is a test result output from the logic circuit 13.

It is intended that the delay unit 10 according to the embodiment illustrated in FIG. 8 measures a delay amount in the delay line 11 against the delay setting data, in the manufacturing process of the semiconductor device 1 to which the delay unit 10 is provided. The test signal input unit 16, the test control signal input unit 18, and the test output unit 14 are electrode pads of the semiconductor device 1, and each of the units includes one or more electrode pads, which is contacted by a probe of a tester that inspects the semiconductor device (chip) on a wafer. A test signal and a test control signal are output from the tester, and a signal output from the test output unit 14 is input to the tester. In addition, the switch 15 is in a state in which an input signal is selected at normal operation, and when the tester probe contacts the test signal input unit 16, the switch 15 performs a switching so as to select a test signal input from the test signal input unit 16. Similarly, the switch 17 is in a state in which a delay setting data is selected at normal operation, and when the tester probe contacts the test control signal input unit 18, the switch 17 performs a switching so as to select a test control signal input from the test control signal input unit 18.

Note that the test output unit 14, the test signal input unit 16, and the test control signal input unit 18 illustrated in FIG. 8 are examples, and instead of providing these, an existing external terminal of the semiconductor device 1 may be used for input/output of a test signal and a test control signal. In addition, a test signal and a test control signal may be generated using a circuit provided to the semiconductor device 1 without providing the switch 15 and the switch 17.

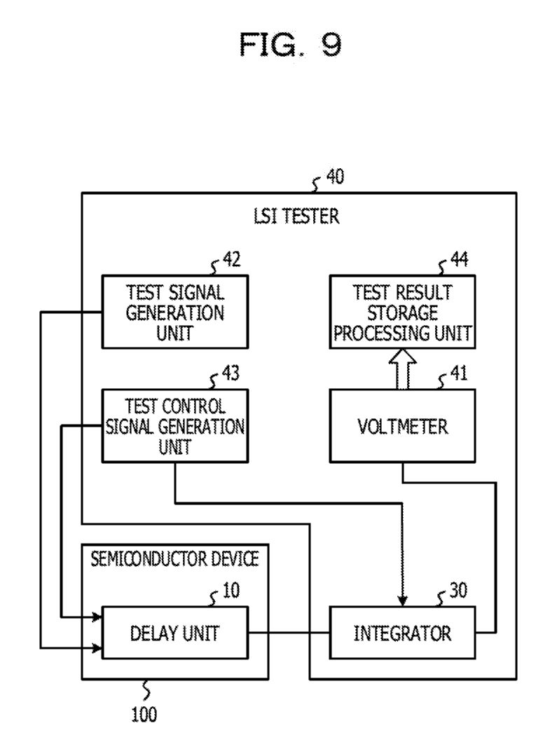

FIG. 9 is a diagram illustrating a configuration of a test system that tests a delay amount in the delay unit according to the embodiment provided in the semiconductor device.

As described above, the test system uses a LSI tester 40 that is used in the manufacturing process of the semiconductor device 1. The LSI tester 40 includes an integrator 30, a voltmeter 41, a test signal generation unit 42, a test control signal generation unit 43, and a test result storage processing unit 44. Note that the integrator 30 may be provided externally at an appropriate position between the probe and the LSI tester main body, or inside the semiconductor device.

The test signal generation unit 42 generates a test signal described later, and supplies the test signal to the delay line 11 through the probe and the test signal input unit 16 of the delay unit 10. The test control signal generation unit 43 generates delay setting data increased or decreased in units of one unit, and supplies the delay setting data to the delay line control circuit 12 through the probe and the test control signal input unit 18 of the delay unit 10. The integrator 30 receives an output of the logic circuit 13 of the delay unit 10 through the test output unit 14 and the probe, and integrates the outputs for a given time period. The voltmeter 41 measures a voltage value of the integrator 30 and supplies the voltage value to the test result storage processing unit 44. The test result storage processing unit 44 stores a voltage value corresponding to each value of the delay setting data, and executes processing in which a change in a voltage value against a change in the delay setting data, namely, a status of change in a delay amount is judged.

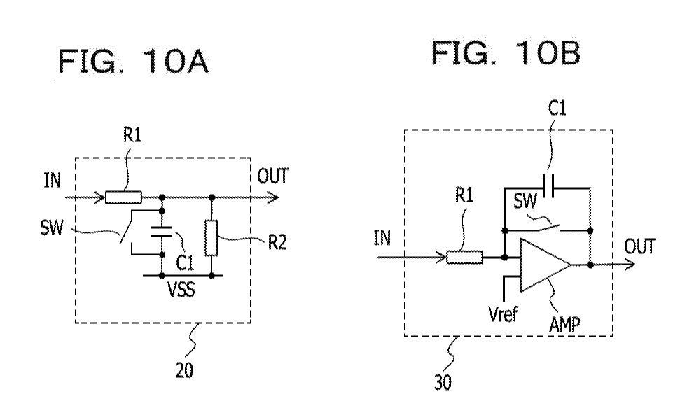

FIGS. 10A and 10B are diagrams each illustrating a configuration example of an integrator. FIG. 10A illustrates an integrator circuit including resistors R1 and R2, a capacity C1, and a switch SW. FIG. 10B illustrates an integrator circuit including a difference amplifier AMP, a resistor R1, a capacity C1, and a switch SW. The integrator circuits are widely known, so that the descriptions are omitted herein.

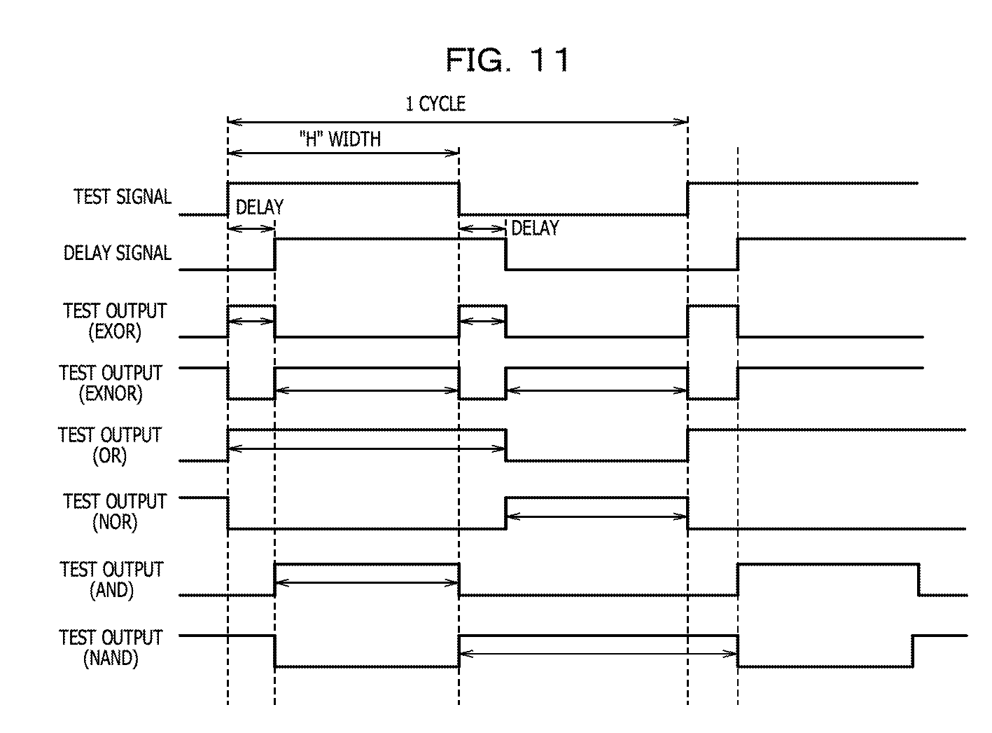

FIG. 11 is a time chart illustrating a waveform of a test signal, a delayed signal, and a test output which is output from the logic circuit 13.

The test signal is a cycle signal that changes between “H” and “L”, and the duty ratio is approximately 50%, and one cycle length of the test signal is twice or more the maximum delay amount of the delay line 11.

A delayed signal output from the delay line 11 is a test signal shifted by the amount of delay. As described above, the one cycle length of the test signal is twice or more the maximum delay amount of the delay line 11, thus, the rising edge of the delayed signal does not exceed the falling edge of the test signal.

The six signals are respectively a test output of the logic circuit 13 when the logic circuit 13 is an EXOR circuit, an EXNOR circuit, an OR circuit, a NOR circuit, an AND circuit, and a NAND circuit. In one cycle of a test signal, the H pulse width of the EXOR test output is delay amount·2. The H pulse width of the EXNOR test output is “one cycle of test signal−delay amount·2”. The H pulse width of the OR test output is “H width of test signal+delay amount”. The H pulse width of the NOR test output is “(cycle of test signal−H width of test signal)−delay amount”. The H pulse width of the AND test output is “H width of test signal−delay amount”. The H pulse width of the NAND test output is “(cycle of test signal−H width of test signal)+delay amount”.

Thus, in any one of the logic circuits, the cycle of the test output is equal to the cycle of the test signal, and the H width is proportional to the delay amount. The duty ratio of the test output is a value obtained by dividing the H width by the cycle of the test signal. The voltage of the integrator 30 is proportional to duty ratio of the test output (namely, delay amount) and the number of repetitions (time) of the test signal, respectively. Therefore, a delay amount may be detected by measuring the voltage of the integrator 13 after having supplied a test signal of a given number of cycles, after connecting the switch of the integrator, resetting the voltage of the integrator, and cutting off the switch. The deterioration is smaller when one signal is output outside the semiconductor device 1 with the duty ratio of the signal maintained, compared to a case in which two signals are output outside the semiconductor device 1 with the delay relationships between the two signals maintained or a delay amount of a few ps is measured. In the integrator 13, charge leakage is little in a short time, and the voltage is accurately proportional to the duty ratio of the test output. The voltmeter 41 is capable of measuring the voltage with a resolution of from one few-thousandth to one ten-thousandth, so that a delay amount per stage may be measured with sufficient accuracy in delay lines of approximately 1000 stages.

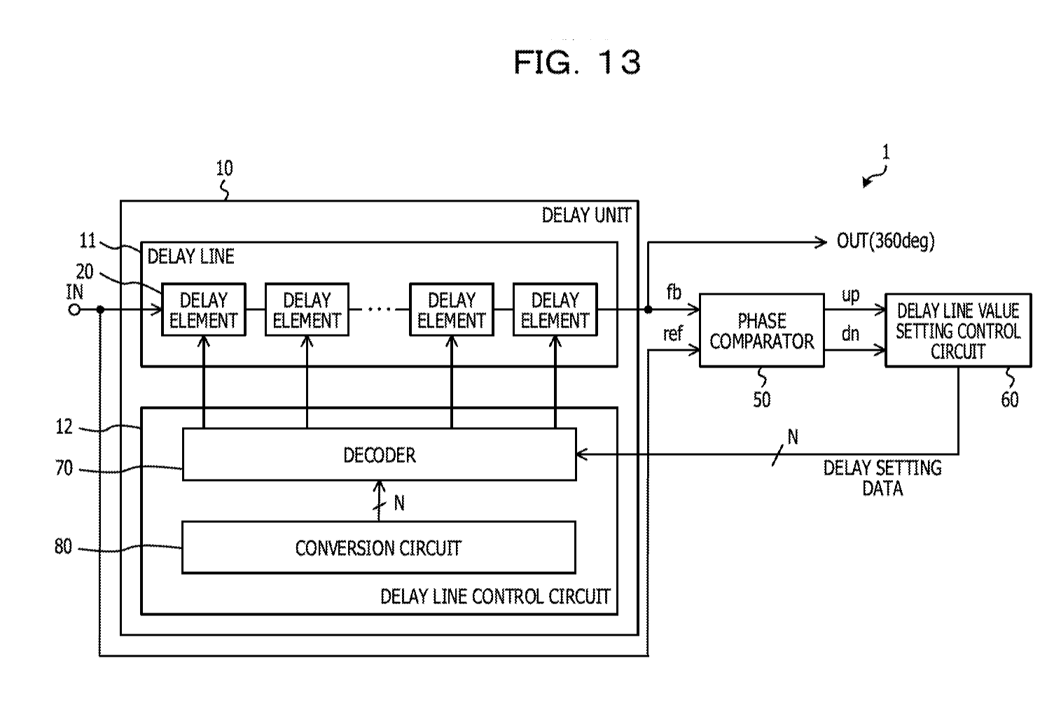

FIG. 13 is a diagram illustrating an example of a configuration of a DLL circuit using the delay circuit (delay unit) according to the embodiment. The DLL circuit in FIG. 13 is differs from the DLL circuit in FIG. 1 in that a conversion circuit 80 is provided in the delay line control circuit 12. The delay line value setting control circuit 60 outputs the same delay setting data as in FIG. 1, and the conversion circuit 80 outputs replaced delay setting data. The decoder 70 decodes a converted delay setting data output from the conversion circuit 80, generates a delay control signal for specifying a delay element of a feedback position, and supplies the delay control signal to the delay line 11.

The conversion circuit 80 is implemented, for example, by a nonvolatile memory, receives delay setting data as an address input, and outputs the replaced, delay setting data as data. If there is no fault in the delay unit 10, the conversion circuit 80 outputs the same delay setting data as the input delay setting data. Generation of a delay control signal from the delay setting data in the delay line control circuit 12 does not have to be at high speed, and to implement the conversion circuit 80 by a memory does not pose a problem of a conversion speed. Note that the conversion circuit 80 may also be implemented by a conversion circuit employing a cross bar method or the like.

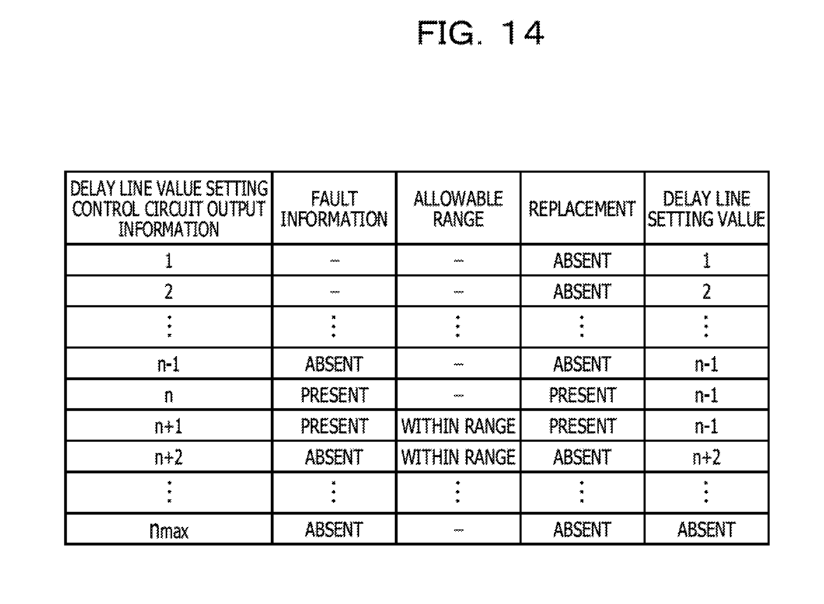

FIG. 14 is a diagram illustrating replacement processing when a measurement value of a delay amount for delay setting data exhibits a characteristic illustrated in FIG. 7A.

In FIG. 14, for each value of delay setting data output from the delay line value setting control circuit, the presence or absence of a fault, whether or not the value is within an allowable range, the presence or absence of replacement, and a replaced delay setting value of the delay line are indicated. The conversion circuit 80 outputs the replaced delay setting value of the delay line as data using the delay setting data as an address.

The embodiments are described above, but it is obvious that various modifications may be implemented. For example, further known configurations may be used for the delay line, the delay line control circuit, and the DLL circuit.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. A delay circuit comprising:
a delay line that delays an input signal in accordance with a delay setting signal and outputs the input signal as a delayed signal; and
a delay line control circuit that generates the delay setting signal in accordance with delay setting data used to specify a delay value in stages and outputs the delay setting signal to the delay line, the delay line control circuit including a conversion circuit that replaces delay setting data to be modified in which a delay amount of a certain range is not obtained with respect to a change in a value of the delay setting data with normal delay setting data in which a delay amount of a certain change range is obtained and that is adjacent to the delay setting data to be modified, based on a measurement value of a delay amount of the delayed signal corresponding to the delay setting data, and outputs the delay setting data to the delay line.

2. A delay locked loop circuit comprising:
a delay circuit that includes
a delay line that delays an input signal in accordance with a delay setting signal, and outputs the input signal as a delayed signal, and
a delay line control circuit that generates the delay setting signal in accordance with delay setting data used to specify a delay value in stages and outputs the delay setting signal to the delay line, and includes a conversion circuit that replaces delay setting data to be modified in which a delay amount of a certain range is not obtained with respect to a change in a value of the delay setting data with normal delay setting data in which a delay amount of a certain change range is obtained and that is close to the delay setting data to be modified, based on a measurement value of a delay amount of the delayed signal corresponding to the delay setting data, and outputs the delay setting data to the delay line;
a phase comparator that detects a phase difference between the input signal and the delayed signal; and
a delay line setting control circuit that changes the delay setting data so that the phase difference detected by the phase comparator becomes a specific value.

3. A fault recovery method of a delay circuit including a delay line that delays an input signal in accordance with a delay setting signal and outputs the input signal as a delayed signal and a delay line control circuit that generates the delay setting signal in accordance with delay setting data used to specify a delay value in stages and outputs the delay setting signal to the delay line, the fault recovery method comprising:
measuring a delay amount of the delayed signal in accordance with the delay setting data; and
replacing delay setting data to be modified in which a delay amount of a certain range is not obtained with respect to a change in a value of the delay setting data with normal delay setting data in which a delay amount of a certain change range is obtained and that is close to the delay setting data to be modified, based on a measurement value of the delay amount.
